(19) United States
(12) Patent Application Publication
(10) Pub. No.: US 2025/0072130 A1
(43) Pub. Date: Feb. 27, 2025

(54) SEMICONDUCTOR DETECTOR

(71) Applicant: KETEK GmbH Halbleiter-und Reinraumtechnik, Muenchen (DE)

(72) Inventor: Florian Wiest, München (DE)

(21) Appl. No.: 18/811,444

(22) Filed: Aug. 21, 2024

(30) Foreign Application Priority Data
Aug. 23, 2023 (DE) 102023122538.3

(51) Int. Cl. H01L 31/117; H01L 31/0216; H01L 31/0224; H01L 31/0352

(52) U.S. Cl. CPC H01L 31/117; H01L 31/02161; H01L 31/022416; H01L 31/03529

(57) ABSTRACT

In an embodiment a semiconductor detector includes a doped semiconductor body with a detection region, a front side and a rear side opposite the front side, a first electrical ring electrode and a second electrical ring electrode arranged around a read-out point on the front side, wherein the ring electrodes are configured to generate an electric field profile in the semiconductor body to guide free charge carriers to the read-out point, the ring electrodes overlapping at least partially with the detection region, as seen in plan view of the front side, a passivation layer arranged on the front side in a direction parallel to the front side between the first ring electrode and the second ring electrode and a first doped layer extending along the front side and electrically conductively connecting the first ring electrode to the second ring electrode without interruptions, wherein the first doped layer and a rest of the semiconductor body are oppositely doped to each other, and wherein a specific resistance of the first doped layer is between 1 Ωcm and 1000 Ωcm, inclusive.

### CROSS-REFERENCE TO RELATED APPLICATIONS

This application claims priority of German application no. 102023122538.3, filed on Aug. 23, 2023, which application is hereby incorporated herein by reference.

### TECHNICAL FIELD

A semiconductor detector is specified.

### SUMMARY

Embodiments provide an improved semiconductor detector that in particular can be operated at a higher operating voltage.

According to at least one embodiment, the semiconductor detector comprises a doped semiconductor body with a detection region, a front side and a rear side which is opposite the front side and via which, in particular, radiation is incident during intended operation. For example, the detection region is also referred to as the space charge zone or depletion zone. In the detection region, the semiconductor body is in particular configured to generate free charge carriers from incident radiation, in particular X-rays. The semiconductor body is formed in particular with silicon.

According to at least one embodiment, a first and a second electrical ring electrode are arranged around a read-out point on the front side. For example, the first and second ring electrodes form concentric rings around the read-out point, as in plan view of the front side. The read-out point is set up in particular to read out a signal from the detector. For example, a current pulse, which represents a detector signal when the detector is in operation, can be read out via the read-out point. The ring electrodes are preferably formed with an electrically conductive material such as a metal. For example, the ring electrodes comprise aluminum. The read-out point is preferably also formed from an electrically conductive material such as a metal. In particular, the read-out point comprises the same material as the ring electrodes. For example, the read-out point forms an anode of the semiconductor detector. A cathode of the semiconductor detector is formed, for example, on the rear side of the semiconductor detector.

According to at least one embodiment, the ring electrodes are configured to generate an electric field profile in the semiconductor body in order to guide free charge carriers to the read-out point. For example, the free charge carriers, such as electrons, are generated by incident radiation in the detection region during intended operation.

The electric field profile is determined in particular by an operating voltage or a potential difference that is applied to the first and second ring electrode. The electric field profile is generated in particular by potentials that are applied to the ring electrodes and to a cathode on the rear side. The electric field profile is generated, for example, by a monotonic potential profile with an extreme value in the region of the read-out point. In intended operation, an electrical potential of −20 V is applied to the first ring electrode, for example, and an electrical potential of −130 V or −230 V is applied to the second ring electrode, whereby the potential difference is 110 V or 210 V respectively. It is possible and advantageous to apply a higher potential difference, for example of at least 200 V, to the ring electrodes during operation.

According to at least one embodiment, the ring electrodes at least partially overlap with the detection region, as in plan view of the front side.

According to at least one embodiment, a passivation layer is arranged on the front side in a direction parallel to the front side between the first ring electrode and the second ring electrode. For example, the passivation layer between the first ring electrode and the second ring electrode is in direct contact with the semiconductor body. The passivation layer comprises, for example, an oxide or a nitride such as silicon oxide, silicon nitride, aluminum nitride or comparable materials.

According to at least one embodiment, the semiconductor body comprises a first doped layer which extends along the front side and electrically conductively connects the first ring electrode to the second ring electrode without interruption. For example, the front side is arranged between the first doped layer and the passivation layer.

According to at least one embodiment, the first doped layer and the remaining semiconductor body are oppositely doped in to each other. For example, the first doped layer is p-doped and the remaining semiconductor body is n-doped or vice versa. In particular, a pn junction is formed in the semiconductor body by the first doped layer. This pn junction is preferably located at an interface between the first doped layer and the rest of the semiconductor body. Here and in the following, the remaining semiconductor body refers in particular to a part of the semiconductor body that is free of the first doped layer. In particular, the pn junction is formed at an interface between the detection region and the first doped layer.

According to at least one embodiment, a specific resistance of the first doped layer is between 1 Ωcm and 1000 Ωcm. In particular due to a resistance of the first doped layer, an electric field profile with a monotonic (logarithmic) potential profile is formed in the semiconductor body during operation of the semiconductor detector by applying an operating voltage to the first and second ring electrode.

In at least one embodiment, the semiconductor detector comprises a doped semiconductor body with a detection region, a front side and a rear side opposite the front side. On the front side, a first and a second electrical ring electrode are arranged around a read-out point, wherein the ring electrodes are configured to generate an electric field in the semiconductor body to guide free charge carriers to the read-out point. The ring electrodes overlap at least partially with the detection region, as seen in plan view of the front side. In a direction parallel to the front side, a passivation layer is arranged on the front side between the first ring electrode and the second ring electrode. The semiconductor body comprises a first doped layer which extends along the front side and electrically conductively connects the first ring electrode to the second ring electrode without interruption. The first doped layer and the rest of the semiconductor body are oppositely doped to each other. A specific resistance of the first doped layer is between 1 Ωcm and 1000 Ωcm.

The semiconductor detector described here is based on the following technical considerations, among others. Typically, in certain semiconductor detectors, such as so-called drift detectors, an electric field profile is generated by applying a voltage to two ring electrodes, by means of which free charge carriers generated in the semiconductor detector are guided to an anode. Between these two ring electrodes, such a detector typically comprises several further conductive rings, which can be made of the same material as the ring electrodes. These rings, also known as drift rings, are connected to each other via implanted resistances, which determine the potential profile and thus the field profile. A total potential difference is typically determined by an operating voltage applied to the two ring electrodes. A dielectric layer is usually provided between the individual rings along the semiconductor body as passivation.

The individual drift rings are usually provided at points where there is no resistance implantation and are coupled via structures that can be described in an equivalent circuit diagram as a long-channel thick-oxide PMOS transistor. An i-th drift ring acts as the source electrode of this transistor structure, an i+1-th drift ring as the drain electrode and the dielectric layer between these two rings as the transistor gate electrode. A drain-source current can be sensitively controlled over many orders of magnitude via the gate of this parasitic transistor structure. In particular, charges in the dielectric layer and at the interface, generated for example by radiation, as well as on the surface, for example accumulated humidity, can influence the gate potential and thus undesirably change the drain-source current.

As soon as the resistance of the parasitic transistor structure becomes smaller than the implanted resistances, this determines the current-voltage characteristics of the drift field and the so-called guard rings. This can result in unstable behavior of the field profile, which leads to unstable detector operation. In extreme cases, the currents across the drift and guard rings become so high that the detector can no longer be operated.

This effect can occur particularly after prolonged irradiation of the detector, as additional oxide and interface charges are generated by the irradiation. Oxide charges and/or an imperfect interface in the form of so-called “dangling bonds” and “near-interface traps” enable the formation of current paths along an interface between the semiconductor body and the dielectric layer. This unstable behavior is particularly prevalent at high operating voltages, as even low oxide and interface charges lead to high, undesirable currents via the drift and guard rings.

A semiconductor detector described herein makes use, inter alia, of the idea of providing a first doped layer on a front side on which two ring electrodes are located. The first doped layer is in particular oppositely doped to the semiconductor body and especially to the detection region of the semiconductor body. Advantageously, charge carriers of this first doped layer compensate for imperfections of an interface between the semiconductor body and the passivation layer and shield the highly sensitive detection region via the generated pn junction. The interface between the semiconductor body and the passivation layer is in particular the front side of the semiconductor body.

One advantage of the semiconductor detector described here is that the first doped layer, and in particular the pn junction generated by it, prevents the detection region from extending to the front side, which forms the interface with the passivation layer. At this interface, uncontrolled interfacial currents can cause a breakdown of a high lateral operating voltage. This significantly reduces the influence of this interface on detector operation.

At the same time, the first doped layer defines a high-impedance resistance between the two ring electrodes. During operation of the semiconductor detector, this resistance fixes a current required for the potential difference between the ring electrodes at a defined value. Typically, this value can range from a few μA to a few 100 μA. In this way, different potentials with a high difference can be applied to the front side at different points. It has proven to be advantageous to provide the semiconductor body with the first doped layer essentially along the entire front side. It has proven particularly advantageous to leave a region of the semiconductor body around the read-out point, to which charge carriers are conducted during operation by means of the electric field profile, free of the first doped layer. The reason for this is that the high-impedance first doped layer could impair the resolution of the detector due to resistance noise.

The possibility of applying an increased operating voltage to the semiconductor detector results in the following advantages, among others. A higher operating voltage allows charge carriers within the semiconductor body to be guided to the read-out point more quickly by means of the higher electric field strengths generated in the field profile. In other words, a drift velocity can be increased. This results in shorter signal rise times of a detector signal and higher counting rates are possible. Furthermore, the semiconductor body can be made thicker. This means that an expansion of the semiconductor body perpendicular to the front side can be chosen to be larger in order to increase the absorption capacity and thus the quantum efficiency of the detector. The conventional thicknesses of 260 μm to 650 μm can thus be advantageously increased to thicknesses of up to one millimeter and more.

The fact that an influence of an interface between the semiconductor body and the passivation layer on the detector operation is reduced in the semiconductor detector described here results in the following advantages, among others:

The function of the ring electrodes is less degraded by exposure to radiation, resulting in increased radiation hardness of the semiconductor detector.

Furthermore, the ring electrodes react less sensitively to environmental influences such as humidity, which is why further passivation or minimum thicknesses for the passivation layer can be largely omitted.

In addition, a quality of the passivation layer plays a much less important role, which can be used to simplify the manufacturing process.

The resistance of the first doped layer, which is preferably formed essentially over the entire surface, does in particular not depend on lithographic manufacturing tolerances, which is why it can advantageously be manufactured within narrower limits. This also advantageously results in a low current dispersion between the ring electrodes.

Furthermore, a manufacturing process for the semiconductor detector can be simplified, for example by doping the first doped layer by means of diffusion of dopants from the passivation layer.

According to at least one embodiment, the semiconductor detector is configured to apply a potential difference of more than 100 V, preferably more than 200 V, more preferably more than 300 V, between the first ring electrode and the second ring electrode during intended operation. The advantages described above can be achieved with a high potential difference.

According to at least one embodiment, the semiconductor detector comprises a radiation entry region on the rear side. The rear side is, for example, partially formed by the radiation entry region. The radiation entry region is completely covered by a second doped layer, which is oppositely doped to the semiconductor body. In particular, the semiconductor body comprises the second doped layer. Preferably, the second doped layer comprises the rear side of the semiconductor body. For example, the second doped layer is p-doped. Boron atoms, for example, are introduced as dopants in the second doped layer. For example, a fourth ring electrode is located on the rear side.

Between the second doped layer and the rear side, the semiconductor body can comprise a third doped layer, which differs from the second doped layer with respect to a degree of doping. The third doped layer preferably has a higher dopant concentration than the second doped layer. In particular, the second and third doped layers are doped with the same dopant.

When the term dopant concentration is used here and in the following, it is preferably referred to an average dopant concentration.

In particular, the radiation entry region forms a radiation entry window for radiation that is detected during operation by means of the semiconductor body. Within the second doped layer, the detection region of the semiconductor body can advantageously be arranged at a distance from the rear side. This allows the detection region to be particularly advantageously protected against environmental influences and the like.

According to at least one embodiment of the semiconductor detector, the first doped layer has a thickness between 0.01 μm and 10 μm, inclusive. Alternatively or additionally, a resistance of the first doped layer, measured between the first and the second ring electrode, is between 0.1 MΩ and 100 MΩ, inclusive. It has been found that with such values for the thickness and/or resistance of the first doped layer, particularly advantageous operation of the semiconductor detector is possible. In particular, an influence of the interface between the semiconductor body and the passivation layer on the detection region can be kept particularly low with such a thickness.

According to at least one embodiment of the semiconductor detector, the semiconductor body, in particular the detection region, is n-doped and the first doped layer is p-doped. A first dopant concentration in the first doped layer is between 5×10¹² cm⁻³ and 1×10¹⁵ cm⁻³, inclusive. A dopant of the first doped layer is, for example, boron.

According to at least one embodiment of the semiconductor detector, the semiconductor body comprises an anode region on the front side, which is bounded in lateral directions by the first doped layer. In the anode region, the semiconductor body is at least partially in direct contact with the passivation layer. The anode region can be recognized, for example, as a region within the first ring electrode when viewed from the front side. In the anode region, the semiconductor body is in direct or indirect contact with the read-out point.

Lateral directions here and in the following refer to directions parallel to the front side of the semiconductor body.

In particular, the semiconductor body comprises an anode contact region in the anode region, which is in direct contact with the read-out point. The anode contact region differs in particular from the rest of the semiconductor body in a dopant concentration. For example, the anode contact region is doped with the same conductivity type as the rest of the semiconductor body, in particular the detection region. For example, the semiconductor body in the anode contact region is n-doped, and the dopant concentration is greater than that of the rest of the semiconductor body. In plan view of the front side, the read-out point preferably covers the anode contact region completely. In particular, free charge carriers in the semiconductor body can be tapped through the anode region and the anode contact region, and a detection signal can be generated.

According to at least one embodiment, the semiconductor body comprises a first contact region and a second contact region. The first contact region directly adjoins the first ring electrode, and the second contact region directly adjoins the second ring electrode. The first contact region and the second contact region are each doped with the same conductivity type as the first doped layer and each have a dopant concentration that is greater than a first dopant concentration of the first doped layer. The increased dopant concentration within the contact regions allows a good electrical connection of the ring electrodes to the semiconductor body.

According to at least one embodiment, the first doped layer comprises a plurality of annular doped regions arranged around the read-out point. A dopant concentration of the doped regions is greater than the first dopant concentration of the first doped layer. Preferably, the doped regions are doped with the same conductivity type as the first doped layer. In particular, the doped regions each directly adjoin the front side of the semiconductor body and to the passivation layer. For example, the doped regions are ring-shaped regions that surround the read-out point in the center.

According to at least one embodiment, at least two different annular doped regions have different widths from each other. In particular, the width is measured in a direction parallel to the front side and away from the read-out point.

For example, a specific resistance or a resistance of the first doped layer, in particular in the doped regions, can be adjusted by means of the doped regions. For example, the resistance can be adjusted via a width or the dopant concentration of the doped regions. Advantageously, the specific resistance of the first doped layer, the total resistance of the first doped layer and/or the electric field profile can be adjusted. For example, a steeper potential profile can be achieved by decreasing the width of the doped regions quadratically with the distance to the read-out point. The dopant concentration of the doped regions offers a further degree of freedom for adjusting the steepness of the potential profile.

According to at least one embodiment, the semiconductor body comprises an edge region that completely surrounds the detection region in lateral directions in plan view of the front side. Preferably, a third ring electrode is arranged on the front side of the semiconductor body in the edge region. In a direction parallel to the front side, the passivation layer is arranged on the front side between the second ring electrode and the third ring electrode. The first doped layer electrically conductively connects the second ring electrode and the third ring electrode without interruption. The edge region is also known as the guard region. Accordingly, the third ring electrode can be referred to as the guard electrode.

Preferably, the semiconductor body is doped in the edge region. For example, the semiconductor body in the edge region has the same conductivity type as the semiconductor body in the detection region. It is possible that a dopant concentration of the semiconductor body in the edge region has a similar value or has essentially the same value as a dopant concentration in the detection region. In particular, the edge region is configured to dismantle an electric field that forms within the semiconductor body during operation, so that the electric field disappears completely at an outer edge of the semiconductor body. In particular, the electric field disappears completely in a border region of the edge region. Preferably, the semiconductor body is potential-free in the border region. The border region preferably borders directly on the outer edge of the semiconductor body. In particular, the outer edge connects the rear side to the front side. In view of the front side, the border region is covered by the third ring electrode, for example. In other words, in the edge region, the potential in a defined area around the outer edge, the border region, which is smaller than the edge region, is drawn to ground. Preferably, the third ring electrode is connected with the lowest possible resistance to a detector base body such as the semiconductor body, an outer side of the first doped layer and the ground.

According to at least one embodiment, the semiconductor body has a third contact region in which the semiconductor body directly adjoins the third ring electrode. The third contact region comprises a first sub-region and a second sub-region. The first sub-region is in direct contact to the first doped layer, and the second sub-region is in direct contact to the first sub-region and the first doped layer. The first sub-region is doped with the same conductivity type as the first doped layer and has a higher dopant concentration than the first doped layer. The second sub-region is oppositely doped to the first sub-region. In particular, this means that the second sub-region is doped with the same conductivity type as the edge region and/or the detection region. The second sub-region preferably comprises a higher dopant concentration than the edge region and/or the detection region.

Preferably, the second sub-region completely penetrates the first doped layer starting from the front side. This means that the second sub-region preferably adjoins the front side and, on a side opposite the front side, directly adjoins the semiconductor body or the edge region outside the first doped region. In particular, on the side opposite the front side, the second sub-region is in contact with a region of the semiconductor body that has the same conductivity type as the second sub-region.

In particular, the third contact region thus has a highly doped pn junction that is short-circuited via a metal, i.e. in particular the third ring electrode, of the contact region. By means of this short-circuited pn junction, the potential in the border region (as well as in the first doped layer and in the semiconductor body) can be advantageously grounded. It has been shown that even a high detector potential, which results in particular from a high operating voltage, can be stably reduced to ground by means of the edge region and the third contact region.

Advantageously, the edge region can be used to prevent the detection region from reaching a scribed or sawn edge of the semiconductor body.

According to at least one embodiment of the semiconductor detector, the third ring electrode is connected to ground, the first sub-region of the third contact region is p-doped and the second sub-region of the third contact region is n-doped.

According to at least one embodiment, a fourth ring electrode is arranged on the rear side of the semiconductor body. In particular, the fourth ring electrode separates the radiation entry region and the edge region. In addition, a fifth ring electrode can be arranged on the rear side, which can preferably be adjacent to the border region.

In particular, the rear side is formed by the radiation entry region together with the edge region. In particular, this means that in the case in which the semiconductor body comprises a second doped layer, the radiation entry region and edge region are completely covered by the second doped layer.

In particular, a further counter electrode is defined within the second doped layer by means of the fourth ring electrode, which generates an electric field perpendicular to the front side. Due to the second doped layer, a particularly high voltage can be applied to the fourth ring electrode, for example more than 100 V or more than 200 V or more than 300 V. Higher voltages at this counter electrode lead to higher electron drift velocities through the detection region and thus advantageously to faster signal rise times. The counter electrode potential is drawn to ground potential towards the outer edge and/or the border region of the semiconductor body in a similar way to the front side via the resistance of the second doped layer implanted over the entire surface and a fifth ring electrode. As on the front side, the edge region of the semiconductor body can advantageously also be arranged at a distance from the rear side. This allows the edge region to be protected particularly advantageously against environmental influences, radiation damage and the like, which leads to more stable detector operation even after high radiation doses.

According to at least one embodiment, the semiconductor body has a rear contact region in which the semiconductor body is directly adjacent to the fifth ring electrode. The rear contact region has a first subsection and a second subsection. The first subsection is in direct contact to the second doped layer, and the second subsection is in direct contact to the first subsection and the second doped layer. The first subsection is doped with the same conductivity type as the second doped layer and has a higher dopant concentration than the second doped layer. The second subsection is oppositely doped to the first subsection. In particular, this means that the second subsection is doped with the same conductivity type as the edge region and/or the detection region. The second subsection preferably has a higher dopant concentration than the edge region and/or the detection region.

In particular, the rear contact region thus comprises a highly doped pn junction that is short-circuited via a metal of the contact region, i.e. in particular the fifth ring electrode. By means of this short-circuited pn junction, the potential in the border region (as well as in the second doped layer and in the semiconductor body) can be advantageously grounded. It has been shown that even a high detector potential, which results in particular from a high operating voltage, can be stably reduced to ground by means of the edge region and the rear contact region as well as the optional third contact region.

According to at least one embodiment, the semiconductor detector is a silicon drift detector.

According to at least one embodiment of the semiconductor detector, the electric field profile generates a drift field, which is configured to guide charge carriers generated by radiation incidence in the detection region to the read-out point. The charge carriers are preferably electrons.

According to at least one embodiment of the semiconductor detector, the electric field profile is variable by the annular doped regions of the first doped layer. For example, the width and/or doping of the doped regions can be adjusted in order to generate a specific drift field.

According to at least one embodiment of the semiconductor detector, an annular cathode is arranged on the rear side of the semiconductor body, which limits the radiation entry region in lateral directions. For example, a radiation entry window of the semiconductor detector is defined by the ring-shaped cathode.

### BRIEF DESCRIPTION OF THE DRAWINGS

Advantageous embodiments and developments of the semiconductor detector will become apparent from the exemplary embodiments described below in association with the figures. In the exemplary embodiments and figures, similar or similarily acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

FIG. 1 shows a schematic sectional view of a semiconductor detector described herein according to a first exemplary embodiment;

FIG. 2 shows a schematic sectional view of a part of a semiconductor detector described herein according to a second exemplary embodiment;

FIGS. 3 and 4 show schematic sectional views of parts of a semiconductor detector according to the first exemplary embodiment described herein; and

FIG. 5 shows a section of a comparative example in schematic sectional view.

### DETAILED DESCRIPTION OF ILLUSTRATIVE EMBODIMENTS

The semiconductor detector 1 according to the first exemplary embodiment comprises a semiconductor body 2 with a detection region 20, a front side 21 and a rear side 22. The semiconductor body 2 is formed with silicon and is n-doped. In lateral directions, the detection region 20 is completely surrounded by an edge region 8. In particular, the semiconductor detector 1 is a silicon drift detector.

On the front side 21, the semiconductor body 2 comprises a first ring electrode 41, a second ring electrode 42 and a third ring electrode 43. The ring electrodes 41, 42, 43 are configured to form an electric field profile in the semiconductor body 2 in order to guide charge carriers generated by incident radiation in the detection region 20 to a read-out point 5. In the edge region 8, the potential profile of the electric field is drawn to ground in the region of the third ring electrode 43. The edge region 8 has a border region 83 which borders directly on an outer edge 84 of the semiconductor body 2. In the border region, the potential profile of the electric field is drawn to ground. Preferably, the semiconductor body 2 is potential-free in the border region 83. In view of the front side 21, the border region 83 is covered by the third ring electrode 43. The outer edge 84 connects the front side 21 and the rear side 22.

The ring electrodes 41, 42, 43 are cathodes in the present exemplary embodiment and are concentric around the read-out point 5. In the present case, the read-out point 5 is an anode. In operation as intended, free charge carriers are generated in the detection region 20 by incident radiation, in particular X-rays. These free charge carriers are guided to the read-out point 5, i.e. the anode, by means of the electric field profile. In particular, the field profile is formed both by electrode voltages at the ring electrodes 41, 42 and by a potential applied to the rear side 20. The charge carriers collect at the anode and a current pulse can be read out. This allows X-rays to be detected by the semiconductor detector 1.

Along the front side 21, the semiconductor detector 1 has a passivation layer 6 between the first ring electrode 41 and the second ring electrode 42 and between the second ring electrode 42 and the third ring electrode 43. In the present exemplary embodiment, the passivation layer 6 is formed with SiO₂. The passivation layer 6 is also arranged on the front side 21 between the first ring electrode 41 and the read-out point 5.

The semiconductor body 2 comprises a first doped layer 7 on the front side 21. The first doped layer 7 is directly adjacent to the front side 21. The front side 21 is at least partially formed by the first doped layer 7. The first doped layer 7 is oppositely doped to the rest of the semiconductor body 2. That is, in the present exemplary embodiment, the first doped layer 7 is p-doped. For example, the first doped layer 7 contains boron as a dopant with a dopant concentration between 5×10¹² cm⁻³ and 1×10¹⁵ cm⁻³ inclusive. The first doped layer 7 has a specific resistance between 1 Ωcm and 1000 Ωcm and a resistance between 0.1 MΩ and 100 MΩ.

The first doped layer 7 forms a pn junction in the semiconductor body 2, which in particular prevents the detection region 20 from extending to the front side 21 and thus to the passivation layer 6. An influence of an interface between the semiconductor body 2 and the passivation layer 6 on the detection region 20 can therefore be advantageously kept small. In addition, the first doped layer 7 defines a high-impedance resistance between the two ring electrodes 41, 42. This allows a high operating voltage of more than 200 V, for example, to be applied to the first ring electrode 41 and the second ring electrode 42.

In a region around the read-out point 5, the semiconductor body comprises an anode region 23. In lateral directions, the anode region 23 is bounded by the first doped region 7. In the anode region 23, the passivation layer 6 is in direct contact with the detection region 20.

The semiconductor body 2 also comprises a first contact region 24, a second contact region 25, a third contact region 80 and an anode contact region 50. In these regions 24, 25, 80, 50, the first ring electrode 41, the second ring electrode 42, the third ring electrode 43 and correspondingly the read-out point 5 are in direct contact with the semiconductor body 2. In plan view on the front side, the first contact region 24 is covered by the first ring electrode 41, the second contact region 25 by the second ring electrode 42, the third contact region 80 by the third ring electrode 43 and the anode contact region 50 by the read-out point 5.

The first contact region 24 and the second contact region 25 are each doped with the same conductivity type as the first doped layer 7, but have a higher dopant concentration compared to the latter. The anode contact region 50 is doped with the same conductivity type as the detection region 20, but has a higher dopant concentration compared to the latter. A good electrical connection of the first and second ring electrode and read-out point 5 to the semiconductor body 2 is possible via the first and second contact regions 24, 25 and via the anode contact region 50, respectively.

The third contact region 80 has a first sub-region 81 and a second sub-region 82. The first sub-region 81 is doped with the same conductivity type as the first doped layer 7 and has a p-dopant whose dopant concentration is higher than the first dopant concentration of the first doped layer 7. The first sub-region 81 adjoins the first doped layer 7 and the second sub-region 82.

The second sub-region 82 is oppositely doped to the first sub-region 81. In particular, this means that the second sub-region 82 is doped with the same conductivity type as the edge region 8. The second sub-region 82 has a higher dopant concentration than the edge region 8. The second sub-region 82 adjoins the first sub-region 81 and the first doped layer 7. The first sub-region 81 is arranged between the second sub-region 82 and the first doped layer 7. The second sub-region 82 completely penetrates the first doped layer 7 starting from the front side 21. That is, the second sub-region 82 adjoins the front side 21 and, on a side opposite the front side 21, directly adjoins the semiconductor body 2 outside the first doped region 7. On the side opposite the front side 21, the second sub-region 82 is in contact with a region of the semiconductor body 2 that has the same conductivity type as the second sub-region 82.

A pn junction, which is formed between the first sub-region 81 and the second sub-region 82, can advantageously reduce an electric field, for example a drift field, which is generated in the semiconductor body 2 during operation of the semiconductor detector 1, towards the edge of the semiconductor body 2, so that the edge of the semiconductor body 2 is preferably potential-free. For this purpose, the third ring electrode 43 is connected to ground.

On a rear side 22 opposite the front side 21, the semiconductor body 2 has a radiation entry region 3. During intended operation, radiation that is to be detected by the semiconductor detector 1 enters the semiconductor body 2 and in particular the detection region 20 through the radiation entry region 3. The radiation entry region 3 is in particular a part rear side 22.

In the radiation entry region 3, the semiconductor body 2 comprises a second doped layer 30 and a third doped layer 31, which are each oppositely doped to the detection region 20. In the present exemplary embodiment, the second and third doped layers 30, 31 are each p-doped, with the third doped layer 31 having a higher dopant concentration than the second doped layer 30. A dopant of the second and third doped layers 30, 31 is preferably boron. The third doped layer 31 is arranged between the second doped layer 30 and the radiation entry region 3. The second doped layer 30 preferably extends over the entire lateral extent of the semiconductor body 2 along the rear side 22. In particular, this means that the second doped layer 30 is directly adjacent to the rear side 22 outside the radiation entry region 3.

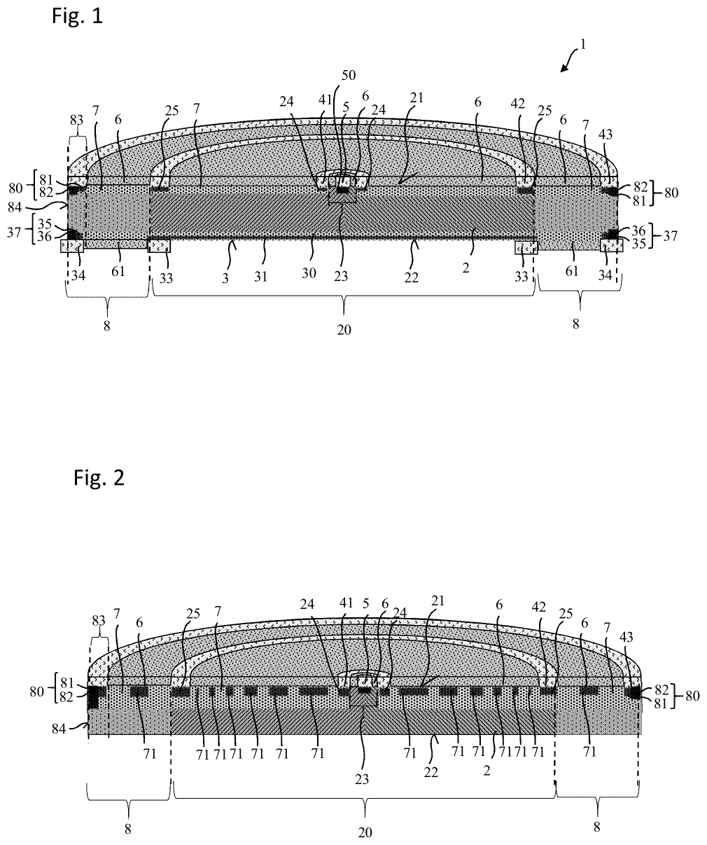

In contrast to FIG. 1, it is also possible for the semiconductor body 2 to contain only the second doped layer 30. In this case, the second doped layer 30 preferably directly adjoins the rear side 22 over the entire lateral extent of the semiconductor body 2.

The second and third doped layers 30, 31 allow the detection region 20 and the edge region 8 to be formed at a distance from the rear side 22. In this way, the influence of an interface of the semiconductor body 2, which is formed by the rear side 22, on these areas can be advantageously kept small.

In the edge region 8 of the semiconductor body 2 and thus outside the radiation entry region 3, the rear side 22 directly adjoins a further passivation layer 61. In particular, the further passivation layer 61 has a similar material as the passivation layer 6. The further passivation layer 61 is disposed along the rear side 22 between an annular cathode 33 and a further annular cathode 34. The ring-shaped cathodes 33, 34 are configured for electric field reduction in the edge region. The further annular cathode 34 is at ground potential, i.e. it is connected to ground.

In the region of the further ring-shaped cathode 34, the semiconductor body 2 comprises a rear contact region 37. The rear contact region 37 has a first subsection 35 and a second subsection 36. The first subsection 35 is doped with the same conductivity type as the second doped layer 30 and has a p-dopant whose dopant concentration is higher than the first dopant concentration of the second doped layer 30. The first subsection 35 adjoins the second doped layer 30 and the second subsection 36.

The second subsection 36 is oppositely doped to the first subsection 35. In particular, this means that the second subsection 36 is doped with the same type of conductivity as the edge region 8. The second subsection 36 has a higher dopant concentration than the edge region 8. The second subsection 36 adjoins the first subsection 35 and the second doped layer 30. The first subsection 35 is arranged between the second subsection 36 and the second doped layer 30.

A pn junction, which is formed between the first subsection 35 and the second subsection 36, can advantageously reduce an electric field, for example a drift field, which is generated the semiconductor body 2 during operation of the semiconductor detector 1, towards the edge of the semiconductor body 2, so that the edge of the semiconductor body 2 is preferably potential-free.

FIG. 2 shows a part of a semiconductor detector 1 according to a second exemplary embodiment. In comparison to FIG. 1, the rear side 22 of the semiconductor body 2 is not shown. The semiconductor detector 1 according to FIG. 2 differs from the semiconductor detector 1 according to FIG. 1 only in that the first doped layer 7 comprises doped regions 71. Like the first doped layer 7, the doped regions 71 are p-doped with boron and have a higher dopant concentration than the first doped layer 7. The doped regions 71 are ring-shaped regions that are arranged concentrically around the read-out point 5. A width of the doped regions 71 decreases with increasing distance from the read-out point 5.

The doped regions 71 can be used to adjust the specific resistance of the first doped layer 7, the total resistance of the first doped layer 7 and/or the electric field profile. For example, a non-parabolic potential profile of the field gradient can be achieved.

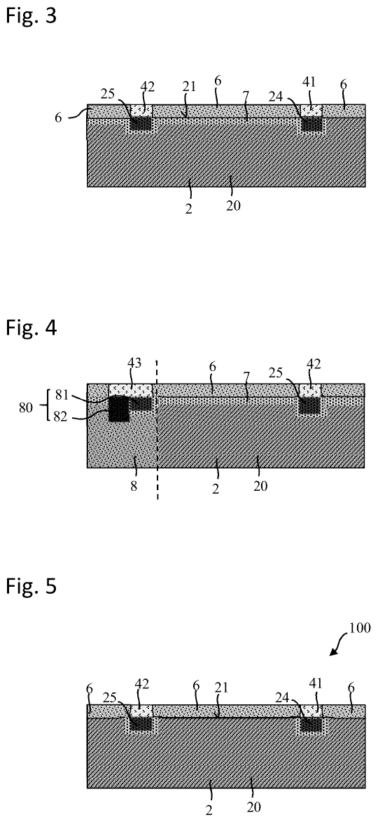

FIGS. 3 and 4 show a detailed view of the semiconductor detector 1 of FIG. 1. It can be seen that the first and second contact regions 24, 25 are directly adjacent to the first doped layer 7 in lateral directions and on a side opposite the ring electrodes 41, 42. Moreover, the detection region 20 is spaced apart from the passivation layer 6 by the first doped layer 7. Furthermore, the first doped layer 7 forms an uninterrupted electrical connection between the first and second ring electrodes 41, 42 (FIG. 3) or between the second and third ring electrodes 42 and 43 (FIG. 4), the resistance of which can be predetermined by a thickness and/or a dopant concentration of the first doped layer 7.

FIG. 5 shows a section of a semiconductor detector according to a comparative example 100. In contrast to a semiconductor detector 1 described here, the comparative example 100 does not have a first doped layer 7 on the front side 21. This means that the detection region 20 is directly adjacent to the passivation layer 6. The section shown in FIG. 5 can be regarded as a parasitic transistor structure in the equivalent circuit diagram, wherein a current flow between the second ring electrode 42 and the first ring electrode 41 can be controlled via interface currents on the front side 21. Thus, the interface between the semiconductor body 2 and the passivation layer 6 undesirably influences the electrical connection between the ring electrodes 41, 42, for example through oxide charges, interfacial charges and the like.

In the semiconductor detector 1 described here, the first doped layer 7 is provided between the passivation layer 6 and the detection region 20, by means of which an influence of the interfaces between semiconductor body 2 and passivation layer 6 on the detector operation can be reduced.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

What is claimed is:

1. A semiconductor detector comprising:
a doped semiconductor body with a detection region, a front side and a rear side opposite the front side;
a first electrical ring electrode and a second electrical ring electrode arranged around a read-out point on the front side,
wherein the ring electrodes are configured to generate an electric field profile in the semiconductor body to guide free charge carriers to the read-out point, the ring electrodes overlapping at least partially with the detection region, as seen in plan view of the front side;
a passivation layer arranged on the front side in a direction parallel to the front side between the first ring electrode and the second ring electrode; and
a first doped layer extending along the front side and electrically conductively connects the first ring electrode to the second ring electrode without interruption,
wherein the first doped layer and a rest of the semiconductor body are oppositely doped to each other, and
wherein a specific resistance of the first doped layer is between 1 Ωcm and 1000 Ωcm, inclusive.

2. The semiconductor detector according to claim 1, where the semiconductor detector is configured to apply a potential difference of more than 200 V between the first ring electrode and the second ring electrode.

3. The semiconductor detector according to claim 2, further comprising an annular cathode arranged on the rear side of the semiconductor body and delimiting a radiation entry region in lateral directions.

4. The semiconductor detector according to claim 1,
wherein the rear side comprises a radiation entry region, and
wherein the radiation entry region is completely covered by a second doped layer which is oppositely doped to the semiconductor body.

5. The semiconductor detector according to claim 1,
wherein a thickness of the first doped layer is between 0.01 μm and 10 μm inclusive, and
wherein a resistance of the first doped layer is between 0.1 MΩ and 100 MΩ inclusive.

6. The semiconductor detector according to claim 1,
wherein the semiconductor body is n-doped and the first doped layer is p-doped,
wherein a first dopant concentration in the first doped layer is between 5×10¹² cm⁻³ and 1×10¹⁵ cm⁻³, inclusive, and
wherein a dopant of the first doped layer is boron.

7. The semiconductor detector according to claim 1,
wherein the semiconductor body comprises an anode region on the front side, which is bounded in lateral directions by the first doped layer, and
wherein, in the anode region, the semiconductor body is at least partially in direct contact with the passivation layer.

8. The semiconductor detector according to claim 1,
wherein the semiconductor body comprises a first contact region and a second contact region,
wherein the first contact region directly adjoins the first ring electrode and the second contact region directly adjoins the second ring electrode, and
wherein the first contact region and the second contact region are each doped with the same conductivity type as the first doped layer and each have a dopant concentration which is greater than a first dopant concentration of the first doped layer.

9. The semiconductor detector according to claim 1,
wherein the first doped layer comprises a plurality of annular doped regions arranged around the read-out point, and
wherein a dopant concentration of the doped regions is greater than a dopant concentration of the first doped layer.

10. The semiconductor detector according to claim 9, wherein at least two different annular doped regions have different widths from each other.

11. The semiconductor detector according to claim 9, wherein the electric field profile is variable by the annular doped regions.

12. The semiconductor detector according to claim 1,
wherein the semiconductor body comprises an edge region which, in plan view of the front side, completely surrounds the detection region in lateral directions,
wherein the semiconductor body comprises a third ring electrode in the edge region on the front side,
wherein the passivation layer is arranged on the front side in a direction parallel to the front side between the second ring electrode and the third ring electrode, and
wherein the first doped layer electrically conductively connects the second ring electrode and the third ring electrode without interruption.

13. The semiconductor detector according to claim 12,
wherein the semiconductor body comprises a third contact region in which the semiconductor body directly adjoins the third ring electrode,
wherein the third contact region comprises a first sub-region which is in direct contact with the first doped layer,
wherein the third contact region comprises a second sub-region which is in direct contact with the first sub-region and the first doped layer,
wherein the first sub-region is doped with the same conductivity type as the first doped layer and has a higher dopant concentration than the first doped layer, and
wherein the second sub-region is oppositely doped to the first sub-region.

14. The semiconductor detector according to claim 13,
wherein the third ring electrode is connected to ground, and
wherein the first sub-region is p-doped and
the second sub-region is n-doped.

15. The semiconductor detector according to claim 1, wherein the semiconductor detector is a silicon drift detector.

16. The semiconductor detector according to claim 1,
wherein the electric field profile generates a drift field, and
wherein the electric field profile is configured to guide charge carriers generated by radiation incidence in the detection region to the read-out point.

17. A semiconductor detector comprising:
a doped semiconductor body with a detection region, a front side and a rear side opposite the front side;
a first electrical ring electrode and a second electrical ring electrode arranged around a read-out point on the front side, wherein the ring electrodes are configured to generate an electric field profile in the semiconductor body to guide free charge carriers to the read-out point, the ring electrodes overlapping at least partially with the detection region, as seen in plan view of the front side;
a passivation layer arranged on the front side in a direction parallel to the front side between the first ring electrode and the second ring electrode;
a first doped layer extending along the front side and electrically conductively connecting the first ring electrode to the second ring electrode without interruption,
wherein the first doped layer and a rest of the semiconductor body are oppositely doped to each other, and
wherein a specific resistance of the first doped layer is between 1 Ωcm and 1000 Ωcm, inclusive;
an edge region which, in plan view of the front side, completely surrounds the detection region in lateral directions; and
a third ring electrode in the edge region on the front side,
wherein the passivation layer is arranged on the front side in a direction parallel to the front side between the second ring electrode and the third ring electrode,
wherein the first doped layer electrically conductively connects the second ring electrode and the third ring electrode without interruption, and
wherein the third ring electrode is connected to ground.
